(19) United States
(12) Patent Application Publication
(10) Pub. No.: US 2026/0215315 A1
(43) Pub. Date: Jul. 23, 2026

(54) SEMICONDUCTOR CHIP LASER BONDING DEVICE

(71) Applicant: VIATRON TECHNOLOGIES, INC., Gyeonggi-do (KR)

(72) Inventors: Hyoung June Kim, Seoul (KR); Byung Kuk Kim, Gyeonggi-do (KR); Maeng Kun Han, Gyeonggi-do (KR); Won Yeong Yang, Gyeonggi-do (KR); Hyun Kyo Lim, Gyeonggi-do (KR); Hyeon Tae Lim, Seoul (KR); Ji Hye Kim, Gyeonggi-do (KR)

(21) Appl. No.: 19/142,591

(22) PCT Filed: Dec. 29, 2023
(86) PCT No.: PCT/KR2023/021978

§ 371 Date: Jun. 23, 2025

(30) Foreign Application Priority Data
Dec. 30, 2022 (KR) 10-2022-0190698

(51) Int. Cl. H10W 72/00

(52) U.S. Cl. CPC H10W 72/07141; H10W 72/07125; H10W 72/07173

(57) ABSTRACT

The present invention discloses a semiconductor chip laser bonding device including s laser irradiation module having laser oscillating regions from which a laser beam is oscillated, the laser oscillating regions being extended in a first direction and spaced apar from each other in a second direction, and laser non-oscillating regions from which no laser beam is oscillated, each laser non-oscillating region being arranged between the laser oscillating regions; and a horizontal transfer module configured to move the laser irradiation module in the second direction, wherein when the laser irradiation module irradiates the laser beam onto an upper surface of a bonding substrate on which a semiconductor chip is mounted, the horizontal transfer module reciprocates the laser irradiation module in the second direction.

### TECHNICAL FIELD

The present disclosure relates to a semiconductor chip laser bonding device that is used to bond a semiconductor chip to a bonding substrate using a laser.

### BACKGROUND ART

Methods for bonding a semiconductor chip (or a die chip) to a substrate include a wire bonding method in which wires are used, and a reflow method in which solder bumps are used. Recently, due to the trend of miniaturizing semiconductor chips, the reflow method using the solder bumps has been widely used. The reflow method includes a heating reflow method in which the solder bump and the semiconductor chip are placed on a substrate and then heated to a high temperature, and a laser bonding method in which the solder bump and the semiconductor chip are placed on the substrate and a laser beam is then irradiated onto an upper surface of the semiconductor chip. As the above substrate, a wafer or a PCB substrate may be used.

Recently, the demand for high-performance semiconductor chips has been increased in line with developments of semiconductor production technology. In addition, the trend is that as the number of I/O terminals on the high-performance semiconductor chip is being increased, the bump pitch is also being decreased. As the bump pitch is decreased, warpage and thermal stress are becoming major issues in the reflow process, and the laser bonding method has been proposed as a way to solve the warpage.

A laser bonding device for the above laser bonding method generally utilizes an optical system to irradiate a laser beam, so an irradiation range of the laser beam is limited to 80 mm×80 mm. In general, the PCB substrate used for the laser bonding method has a rectangular shape of 300 mm×150 mm, and the laser beam should be irradiated approximately six times during the laser bonding process. Therefore, the laser beam is discontinuously irradiated on the PCB substrate is irradiated, which may increase the generation of warpage. In addition, sine the trend is for the thickness of semiconductor chips and PCB substrates to become thinner, there is a possibility that the semiconductor chip and the PCB substrate may be deformed during the laser bonding process.

### DISCLOSURE OF THE INVENTION

### Technical Problem

An object of the present disclosure is to provide a semiconductor chip laser bonding device that can prevent warpage of a PCB substrate from occurring during a laser bonding process for a semiconductor chip.

### Technical Solution

A semiconductor chip laser bonding device of the present disclosure includes a laser irradiation module having laser oscillating regions from which a laser beam is oscillated, the laser oscillating regions being extended in a first direction and spaced apar from each other in a second direction, and laser non-oscillating regions from which no laser beam is oscillated, each laser non-oscillating region being arranged between the laser oscillating regions; and a horizontal transfer module configured to move the laser irradiation module in the second direction, wherein when the laser irradiation module irradiates the laser beam onto an upper surface of a bonding substrate on which a semiconductor chip is mounted, the horizontal transfer module reciprocates the laser irradiation module in the second direction.

Also, the semiconductor chip laser bonding device may further include a bonding chamber, the bonding chamber may include a chamber housing formed in the shape of box, configured to accommodate the bonding substrate therein, and having a laser passing opening formed in an upper plate and corresponding to the bonding substrate; a substrate support supporting the bonding substrate inside the chamber housing; and a laser transmitting plate coupled to the laser passing opening hole.

Furthermore, the chamber housing may further include a substrate entrance formed at one side wall and allowing the bonding substrate to enter the chamber housing, and a substrate exit formed on the other side wall and allowing the bonding substrate to be discharged to the outside; and a gas inlet through which a gas flows into the chamber housing, and a gas outlet through which a gas is discharged to the outside.

In addition, the laser irradiation module may be formed by arranging VCSEL devices in a lattice form on a lower surface of a device array plate, the VCSEL device may have a device region on which laser emitting units, from which the laser beam is oscillated, are mounted, and a terminal region on which terminals supplying power to the laser emitting units are mounted, and the device region may form the laser oscillating region and the terminal region may form the laser non-oscillation region.

Also, the laser oscillating region may be formed to have a width greater than a width of the laser non-oscillating region, and the horizontal transfer module may reciprocate the laser irradiation module a distance greater than a width of the laser non-oscillating region.

Furthermore, the horizontal transfer module may include a horizontal transfer support plate placed behind the laser irradiation module, two horizontal transfer rails secured to a front surface of the horizontal transfer support plate while being extended in a horizontal direction and spaced apart from each other in a vertical direction, a horizontal transfer block coupled to horizontal transfer rails and the laser irradiation module, a horizontal transfer means configured to reciprocate the horizontal transfer block, and a horizontal transfer support column placed behind the horizontal transfer support plate and coupled with the horizontal transfer support plate.

In addition, the horizontal transfer means may include a horizontal ball screw coupled to the horizontal transfer block to move the horizontal transfer block, and a horizontal servo motor coupled to the horizontal balls crew.

Alternatively, the semiconductor chip laser bonding device may further include a vertical transfer module coupled to the horizontal transfer module to move the horizontal transfer module upwards and downwards.

### Advantageous Effects

The semiconductor chip laser bonding device of the present disclosure uses the large-area laser irradiation module on which the VCSEL devices are arranged, but may prevent warpage of the PCB substrate from being occurred in the process of laser-bonding the semiconductor chip to the PCB substrate.

Furthermore, the semiconductor chip laser bonding device of the present disclosure may reciprocate the laser irradiation module in one direction to reduce the temperature deviation of the PCB substrate caused by the terminal region in the process of arranging the VCSEL devices and resulting warpage.

In addition, the semiconductor chip laser bonding device may irradiate the laser beam evenly throughout to bond the semiconductor chip to the bonding substrate with uniform characteristics even when the bump pitch of the bonding substrate is fine.

### BRIEF DESCRIPTION OF THE DRAWINGS

FIG. 1 is a front view of a semiconductor chip laser bonding device according to one embodiment of the present disclosure.

FIG. 2 is a vertical cross-sectional view taken along the line A-A of FIG. 1.

FIG. 3 is a vertical cross-sectional view taken along the line B-B of FIG. 2.

FIG. 4 is a bottom view of a laser irradiation module of FIG. 3.

FIG. 5 is a partial perspective view of a VCSEL device of FIG. 4.

FIG. 6 is a vertical cross-sectional view taken along the line C-C of FIG. 5.

FIG. 7 is a partial enlarged view of “D” of FIG. 2

### BEST MODE FOR CARRYING OUT THE INVENTION

Hereinafter, a semiconductor chip laser bonding device of the present disclosure is described in more detail with reference to embodiments and the accompanying drawings.

First, a semiconductor chip laser bonding device according to one embodiment of the present disclosure is described.

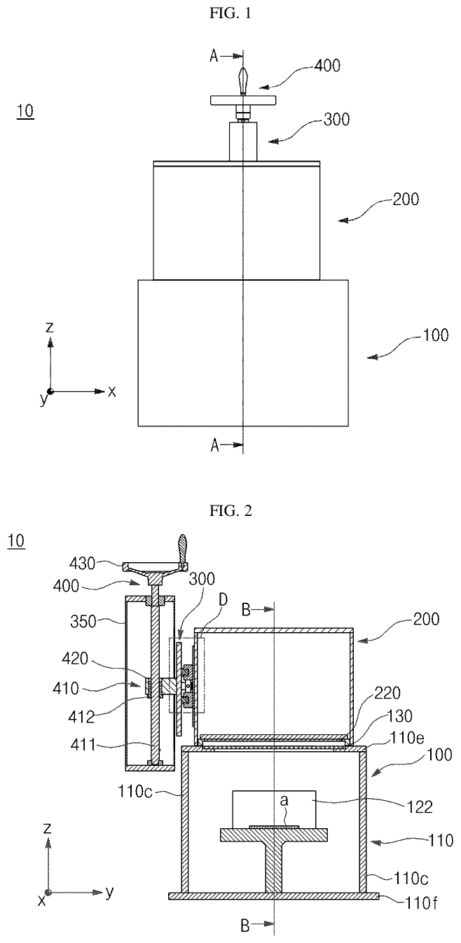

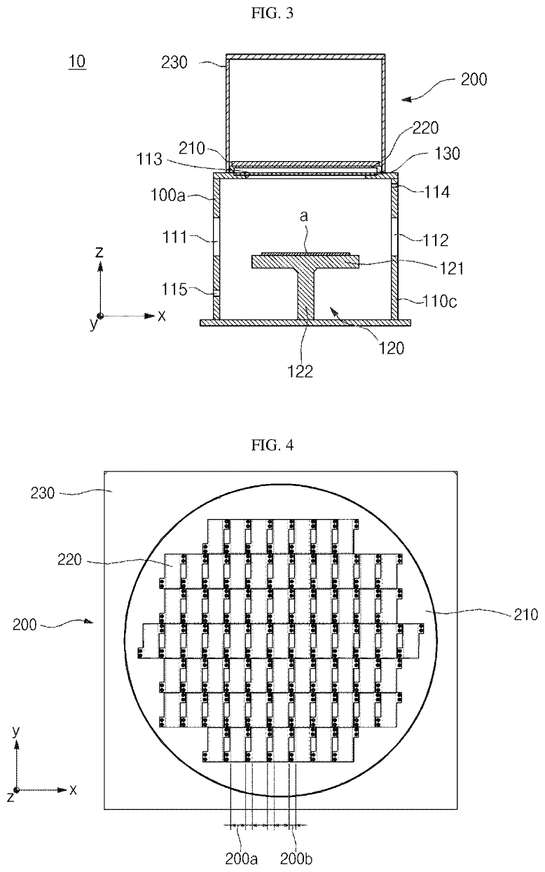

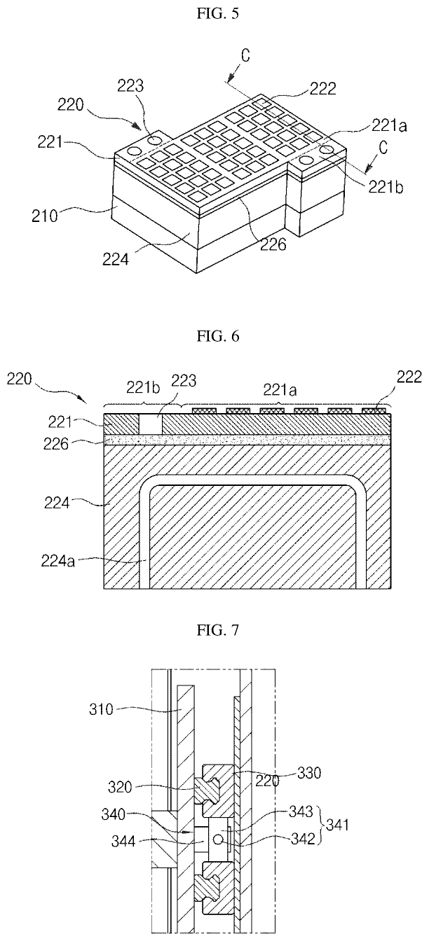

FIG. 1 is a front view of a semiconductor chip laser bonding device according to one embodiment of the present disclosure. FIG. 2 is a vertical cross-sectional view taken along the line A-A of FIG. 1. FIG. 3 is a vertical cross-sectional view taken along the line B-B of FIG. 2. FIG. 4 is a bottom view of a laser irradiation module of FIG. 3. FIG. 5 is a partial perspective view of a VCSEL device of FIG. 4. FIG. 6 is a vertical cross-sectional view taken along the line C-C of FIG. 5. FIG. 7 is a partial enlarged view of “D” of FIG. 2.

Referring to FIGS. 1 to 7, a semiconductor chip laser bonding device 10 according to one embodiment of the present disclosure may include a bonding chamber 100, a laser irradiation module 200, and a horizontal transfer module 300. The semiconductor chip laser bonding device 10 may further include a vertical transfer module 400. In addition, although not specifically depicted, the semiconductor chip laser bonding device 10 may include a substrate supply module for transferring a bonding substrate a, on which a laser bonding is being performed, to an interior of the bonding chamber 100, and a substrate recovery module for transferring the bonding substrate a, on which the bonding is completed, to an exterior of the bonding chamber 100.

In the semiconductor chip laser bonding device 10, the laser irradiation module 200 may irradiate a laser beam to an upper side of the bonding substrate a which is being transferred to a bonding position set inside the bonding chamber 100. Furthermore, in the semiconductor chip laser bonding device 10, the horizontal transfer module 300 may reciprocate the laser irradiation module 200 in a horizontal direction during the bonding process. The bonding substrate a may be a quadrangle-shaped PCB substrate having a width and a length. Also, the bonding substrate a may be a quadrangle-shaped glass substrate having a widths and a length, or a circular-shaped semiconductor wafer having a predetermined a diameter. The bonding substrate a may have a pattern of various electrically conductive pads formed on an upper surface therefore, and solder bumps may be placed on the electrically conductive pads. In addition, a semiconductor chip, which has the electrically conductive pad and a die pad electrically connected to the solder bump, may be placed on the bonding substrate a.

The semiconductor chip laser bonding device 10 may uniformly irradiate the laser beam to the bonding substrate a to prevent warpage from being occurred due to uneven heating of the bonding substrate a. Furthermore, the semiconductor chip laser bonding device may uniformly irradiate the laser beam throughout, even when the bonding substrate a has a fine bump pitch. Thus, the semiconductor chip laser bonding device may bond the semiconductor chip to the bonding substrate a with uniform characteristics. The semiconductor chip laser bonding device 10 may heat the bonding substrate a at the rate of 100° C./s using the laser beam irradiated from the laser irradiation module 200 to the bonding substrate a.

The semiconductor chip laser bonding device 10 may efficiently proceed with the bonding process because the laser irradiation module 200 simultaneously irradiates the laser beam to an irradiation area of 300×300 mm. Also, the semiconductor chip laser bonding device 10 does not use a separate optical system, so the configuration of the device may be simplified. In addition, the semiconductor chip laser bonding device 10 simultaneously irradiates the laser beam to the laser beam irradiation area to proceed with the bonding process, thereby heating the bonding substrate a more uniformly.

Further, the semiconductor chip laser bonding device is formed such that a laser bonding space in which the laser bonding is performed is separated from a space in which the laser irradiation module 200 is placed. In addition, the semiconductor chip laser bonding device is capable of supplying/discharging a transport gas into/from the interior of the bonding chamber 100. Thus, the semiconductor chip laser bonding device may prevent the laser irradiation module 200 and the interior of the bonding chamber 100 from being contaminated by bonding fumes generated during the laser bonding process.

The bonding chamber 100 may include a chamber housing 110, a substrate support 120, and a laser transmitting plate 130. The bonding chamber 100 may provide a space in which the bonding substrate a is placed and a laser bonding process is performed.

The chamber housing 110 may include a substrate entrance 111, a substrate exit 112, and a laser passing opening 113. In addition, the chamber housing 110 may further include a gas inlet 114 and a gas outlet 115.

The chamber housing 110 may be formed in the shape of box having a bonding space formed therein. For example, the chamber housing 110 may be formed into a hexahedral shape including one side wall 110a, the other side wall 110b, a front side wall 110c, a rear side wall 110d, and an upper plate 110e and a lower plate 110f. The chamber housing 110 may provide a space necessary to accommodate the substrate support 120 that supports the bonding substrate a, inside the chamber housing 110.

The substrate entrance 111 may be formed to penetrate one side wall of the chamber housing 110. The substrate entrance 111 may be formed into a shape corresponding to a shape of a vertical cross section of the bonding substrate a. The substrate entrance 111 may be formed to have an area which is at least larger than a vertical cross-sectional area of the bonding substrate a. For example, the substrate entrance 111 may be formed to have a height greater than a thickness of the bonding substrate a and a width greater than a width of the bonding substrate a. In one side wall of the chamber housing 110, the substrate entrance 111 may be formed at a height equal to a height of the substrate support 120. The substrate entrance 111 may provide a pathway through which the bonding substrate a enters to be seated on an upper surface of the substrate support 120.

The substrate exit 112 may be formed to penetrate the other side wall of the chamber housing 110. The substrate exit 112 faces the substrate entrance 111 and may be formed into a shape which is the same as or similar to that of the substrate entrance. The substrate exit 112 may be formed into a shape corresponding to a shape of a vertical cross-section of the bonding substrate a. The substrate exit 112 may be formed to have an area that is at least larger than an area of the vertical cross-section of the bonding substrate a. For example, the substrate exit 112 may be formed to have a height, greater than a thickness of the bonding substrate a, and a width greater than a width of the bonding substrate a. In one side wall of the chamber housing 110, the substrate exit 112 may be formed at a height equal to a height of the substrate support 120. The substrate exit 112 may provide a pathway through which the bonding substrate a to which the semiconductor chip is bonded is discharged.

The laser passing opening 113 may be formed in and pass through the upper plate of the chamber housing 110 may be formed. The laser passing opening 113 may be formed into a shape corresponding to a shape of the bonding substrate a or the substrate support 120. Furthermore, the laser passing opening 113 may be formed to have an area larger than a planar area of the bonding substrate a. In addition, the laser passing opening 113 may be formed to have an area equal to an area of the substrate support 120. The laser passing opening 113 may be positioned above the bonding substrate a. The laser passing opening 113 may provide a pathway through which the laser beam oscillated from the laser irradiation module 200 placed above the chamber housing 110 is irradiated onto the upper surface of the bonding substrate a.

The gas inlet 114 may be formed in and pass through any one side wall of the chamber housing 110. The gas inlet 114 may preferably be formed in the other side wall, on which the substrate entrance 112 is formed, at a height which is equal to or greater than that of the substrate exit 112. The gas inlet 114 may provide a passage into which a transfer gas, which transfers bonding fumes generated during a laser bonding process, inflows. The transfer gas may be an inert gas, such as nitrogen gas or argon gas.

The gas outlet 115 may be formed in one, that faces a side wall in which the gas inlet 114 is formed, of the side walls of the chamber housing 110. For example, the gas outlet 115 may be formed in one side wall of the chamber housing 110. Further, the gas outlet 115 may be formed in a lower portion of the sidewall of the chamber housing 110. The gas outlet 115 may provide a passageway through which the transfer gas, which is mixed with bonding fumes, is discharged to the exterior of the chamber housing 110.

The substrate support 120 may include a support main body 121. Further, the substrate support 120 may further include a main body support bar 122. The substrate support 120 may be placed inside the chamber housing 110 to support the bonding substrate a. The substrate support 120 may be placed such that its upper surface is at the same height as a height of the substrate entrance 111. Thus, the substrate support 120 may stably support the bonding substrate a entering through the substrate entrance 111. Further, the substrate support 120 may heat the bonding substrate a to a predetermined bonding temperature. The bonding temperature may be 150 to 350° C.

Although not specifically depicted, the substrate support 120 may further include an eject pin for transferring the bonding substrate a resting on an upper surface of the support main body 121 upwards. This eject pin may be a typical eject pin used for a susceptor in a semiconductor device manufacturing apparatus.

The support main body 121 may be formed as a block in the shape of a circular plate or a quadrangle plate. The bonding substrate a may be supported by the support main body 121 by being placed on the upper surface of the support main body. Thus, the support main body 121 may be formed to have a thickness necessary to stably support the bonding substrate a. In addition, the support main body 121 may include a heating wire or heating means provided therein. Accordingly, the support main body 121 may heat the bonding substrate a to a predetermined bonding temperature. In addition, the support main body 121 may further include an electrostatic electrode, that generates an electrostatic force and is provided within the support main body. Thus, the support main body 121 may stably support the bonding substrate a using an electrostatic force.

The main body support bar 122 may be formed in the shape of a bar extended upwards and downwards. The main body support bar 122 may be coupled to a lower surface of the support main body 121. The main body support bar 122 may be coupled to the lower plate of the chamber housing 110 via a lower end thereof. The main body support bar 122 may support the support main body 121 such that the upper surface of the support main body 121 is at a height corresponding to the substrate entrance 111. Further, the main body support bar 122 may be coupled to a separate transferring means to be transferred upwards and downwards, without being coupled to the lower plate of the chamber housing 110.

The laser transmitting plate 130 may be formed into the same shape as a planar shape of the laser passing opening 113. The laser transmitting plate 130 may be formed from a transparent material such as quartz. The laser transmitting plate 130 may be coupled to the laser passing opening hole 113 to shield the laser passing opening 113. The laser transmitting plate 130 may allow the laser beam oscillated from the laser irradiation module 200 placed above the chamber housing 110 to penetrate it and irradiate the upper surface of the bonding substrate a.

The laser irradiation module 200 may include a device array plate 210, VCSEL devices 220, and a laser support housing 230. The laser irradiation module 200 may be placed above the bonding chamber 100 to irradiate a laser beam onto the upper surface of the bonding substrate a. In other words, the laser irradiation module 200 may irradiate the laser beam in a downward direction. In the laser irradiation module 200, a variety of devices oscillating the laser beam may be utilized. In the laser irradiation module 200, for example, the VCSEL device 220 may be employed. The laser irradiation module 200 may be coupled to the device array plate 210 such that the VCSEL device 220 faces downward. The laser irradiation module 200 may be placed above the laser transmitting plate 130 on the outside of the chamber housing 110. As described above, the laser irradiation module 200 may utilize a variety of devices oscillating the laser beam, in addition to the VCSEL device 220.

The laser irradiation module 200 may include laser oscillating regions 200a in which the laser beam is oscillated from the VCSEL device 220, and laser non-oscillating regions 200b in which no laser beam is oscillated. In other words, the laser irradiation module 200 may include the laser oscillating regions 200a extended in a first direction, spaced apart from each other in a second direction and configured to oscillate the laser beam, and the laser non-oscillating regions 200b, each of which being arranged between the laser oscillating regions 200 and configured not to oscillate the laser beam. In the laser irradiation module 200, the laser oscillating regions 200a are extended in the first direction which is the y direction, and may be spaced apart from each other in the second direction which is the x direction. Each laser non-oscillating region 200b is arranged between the laser oscillating regions 200a, and the laser non-oscillating regions may be extended in the first direction and spaced apart each other in the second direction. The laser oscillating region 200a may be formed to have a width larger than that of the laser non-oscillating region 200b. Furthermore, the laser non-oscillating region 200b may have a width greater than a bump pitch of the bonding substrate a. The laser non-oscillating region 200b may be formed to have a width of approximately 5 to 10 mm. Further, the laser non-oscillating regions 200b may be formed continuously or discontinuously. When the laser non-oscillating regions 200b are formed discontinuously, it may mean that the laser oscillating regions 200a are formed discontinuously in the middle. Here, the first and second directions may refer to the directions which form a right angle with each other. Furthermore, in addition to the directions forming a right angle, the first and second directions may also be the directions extended to form an obtuse or acute angle with each other. However, hereinafter, the laser irradiation module is described based on a relation that the first and second directions form a right angle. That is, the laser irradiation module is described based on a relation that the first direction is the y direction and the second direction is the x direction.

In the laser irradiation module 200, the plurality of VCSEL devices 220 may be arranged in a lattice form on an upper surface of the device array plate 210. Referring to FIGS. 4 and 5, the VCSEL devices 220 may be arranged on the upper surface of the device array plate 210 in the first direction and the second direction to be arranged in a grid shape.

The laser irradiation module 200 may be reciprocated in a direction orthogonal to the direction in which the laser oscillating regions 200a are extended. Thus, the y direction is a direction in which the laser oscillating regions 200a are extended, and the x direction is a direction in which the laser irradiation module 200 is reciprocated. Further, when the laser oscillating regions 200a are extended in the x direction, the laser irradiation module 200 may be reciprocated in the y direction. Thus, the laser irradiation module 200 may uniformly irradiate the laser beam onto the bonding substrate a regardless of the extending direction of the laser oscillating regions 200a and the laser non-oscillating regions 200b. If the laser irradiation module 200 irradiates the laser beam onto the bonding substrate a in a state in which it is fixed, a solder pump on the bonding substrate a placed below the laser non-oscillating region 200b is not sufficiently heated, so the bonding may not be performed normally.

The device array plate 210 may be formed in the shape of a plate having predetermined area and thickness. The device array plate 210 may preferably be formed to have a diameter larger than a length of the bonding substrate a. The device array plate 210 may be formed from a thermally conductive ceramic material or metallic material. The device array plate 210 may function to radiate heat generated by the VCSEL device 220.

The VCSEL device 220 may include a device substrate 221, a laser emitting unit 222, an electrode terminal 223, and a cooling block 224. The plurality of the VCSEL devices 220 may be arranged and positioned on the device array plate 210 in a lattice direction. The VCSEL devices 220 may be arranged on a region of a surface of the device array plate 210, which is necessary to irradiate the laser beam onto a region of the bonding substrate a. The device substrate 221 may be coupled to the cooling block 224 by a separate adhesive layer 226.

The plurality of VCSEL devices 220 may be supplied with a supply current such that the light output becomes uniform. That is, the supply current supplied to each of the VCSEL devices 220 may be individually controlled to allow the light output to be uniform as a whole. Here, the light output may refer to the radiant energy or power of the laser beam irradiated by the VCSEL devices 220. The light output may be measured using measurement means such as a pyrometer or a laser power meter. Further, the VCSEL devices 220 may be individually supplied with different supply currents based on a pre-evaluated relation between a supply current and the light output. Thus, the VCSEL devices 220 may control the overall light output uniformly and reduce a temperature deviation of the bonding substrate a.

Since the laser emitting unit 222 constituting the VCSEL device 220 has unique luminance efficiency, the light output may not be the same even if the same current is supplied to the VCSEL device. Therefore, after the output of each VCSEL device according to the supply current is pre-measured and the supply current for the required output is individually determined, the VCSEL devices 200 may be supplied with the determined supply current.

The VCSEL device 220 is formed by arranging the plurality of laser emitting units 222 in the x axial direction and the y axial direction. Although not specifically depicted, the VCSEL device 220 may be provided with a light-emitting frame (not shown) for securing the laser emitting units 222 and a power line (not shown) for supplying the current to the laser emitting units 222. The VCSEL device 220 may be formed such that the same current is applied to all the laser emitting units 222. Alternatively, the VCSEL device 220 may be formed such that different powers are applied to the laser emitting units 222, respectively.

A general substrate used for mounting electronic devices may be employed as the device substrate 221. The device substrate 221 may be divided into a device region 221a on which the laser emitting units 222 are mounted, and a terminal region 221b on which terminals supplying power to the laser emitting units 222 are mounted. On the device region, the plurality of laser emitting units 222 are arranged and mounted in a grid shape. The terminal region 221b is disposed adjacent to the device region 221a, and a plurality of terminals may be mounted on the terminal region. The device region 221a may form the laser oscillation region 200a in the laser irradiation module 200, and the terminal region 221b may form the laser non-oscillation region 200b.

The laser emitting unit 222 may be formed of various light emitting elements that irradiate a laser beam. Preferably, a VCSEL (vertical cavity surface emitting laser) unit may be employed as the laser emitting unit 222. The laser emitting unit 222 may irradiate the laser beam of a single wavelength of 940 nm. The laser emitting unit 222 may be formed into a quadrangle shape, preferably a square shape, or a rectangular shape with the ratio of width to length not exceeding 1:2. The VCSEL unit is manufactured as a hexahedral-shaped chip, and a high-power laser beam is oscillated from one surface of this unit. Since the laser emitting unit 222 oscillates the high-powered laser beam, compared to a conventional halogen lamp, it may increase a temperature rise rate of the bonding substrate a and its life span is relatively long.

The plurality of laser emitting units 222 may be arranged in the device region 221a on an upper surface of the device substrate 221 in the x-direction and the y-direction to be arranged in the form of a lattice. The suitable number of laser emitting units 222 may be formed at suitable intervals depending on the area of the device region 221a and the energy amount of the laser beam irradiated to the bonding substrate a. Further, the laser emitting units 222 may be spaced apart from each other such that they may irradiate uniform energy when the emitted laser beam overlaps with the laser beam of adjacent laser emitting unit 222. At this time, the laser emitting units 222 may be placed such that side surfaces of the adjacent laser emitting units 222 are in contact with each other to allow no gap to be generated therebetween.

The plurality of electrode terminals 223 may be formed on the terminal region 221b of the device substrate 221. The electrode terminals 223 includes a + terminal and a − terminal, and may be electrically connected to the laser emitting unit 222. Although not specifically depicted, the electrode terminals 223 may be electrically connected to the laser emitting unit 222 in various ways. The electrode terminals 223 may supply the current required to drive the laser emitting unit 222.

The cooling block 224 may be formed to have a plane shape, which corresponds to a plane shape of the device substrate 221, and a predetermined height. The cooling block 224 may be formed from a thermally conductive ceramic material or metal material. The cooling block 224 may be coupled to a lower surface of the device substrate 221 by a separate adhesive layer. The cooling block 224 may dissipate heat generated from the laser emitting unit 222 mounted on a surface of the device substrate 221 downward. Therefore, the cooling block 224 may cool the device substrate 221 and the laser emitting unit 222.

A cooling passage 224a through which coolant flows may be formed in the cooling block 224. The cooling passage 224a have an inlet and an outlet formed in a lower surface of the cooling block, and may be formed with an inlet and an outlet on the bottom surface, and may be formed in various configurations inside the cooling block 224.

The laser support housing 230 may be formed in the shape of a box with a hollow interior. The laser support housing 230 may be formed to have a horizontal area larger than the area of the device array plate 210. The device array plate 210 may be coupled to a lower plate of the laser support housing 230. The laser support housing 230 may support the device array plate 210, and an electrical terminal and an electrical line (not shown) connected to the VCSEL device 220, a cooling water terminal and a cooling water line (not shown), and the like may be housed in the laser support housing. The laser support housing 230 may be reciprocated in the y direction together with the device array plate 210.

The horizontal transfer module 300 may include a horizontal transfer support plate 310, a horizontal transfer rail 320, a horizontal transfer block 330, and horizontal transfer means 340. Further, the horizontal transfer module 300 may further include a horizontal transfer support column 350.

The horizontal transfer module 300 is coupled to the laser irradiation module 200, and may be coupled to a rear side or an upper side of the laser irradiation module 200. The horizontal transfer module 300 may reciprocate the laser irradiation module 200 in a direction orthogonal to the direction in which the laser oscillating regions 200a are extended. The horizontal transfer module 300 may reciprocate the laser irradiation module 200 a width greater than a width of the laser non-oscillating region 200b.

The horizontal transfer support plate 310 may be formed in the shape of plate having predetermined thickness and area. The horizontal transfer support plate 310 may be formed to have an area required for securing two horizontal transfer guides. The horizontal transfer support plate 310 may be placed to be spaced apart from the laser irradiation module 200. More specifically, the horizontal transfer support plate 310 may be spaced apart from a rear side or an upper side of the device array plate 210 or the laser support housing 230 of the laser irradiation module 200.

A conventional linear motion (LM) guide rail may be used as the horizontal transfer rail 320. The horizontal transfer rail 320 may be coupled to a front surface of the horizontal transfer support plate 310.

The two horizontal transfer rails 320 may be secured to a front surface of the horizontal transfer support plate 310 while being extended in a horizontal direction and spaced apart from each other in a vertical direction. The horizontal transfer rails 320 may be formed to have a length longer than a distance that the laser irradiation module 200 is moved in the horizontal direction.

A conventional LM block may be used as the horizontal transfer block 330. The two horizontal transfer blocks 330 may be coupled to the horizontal transfer rails 320, respectively. Further, the horizontal transfer blocks 330 may be coupled to the laser irradiation module 200. For example, the horizontal transfer blocks 330 may be coupled to the device array plate 210 or the laser support housing 230 of the laser irradiation module 200. The horizontal transfer blocks 330 may be reciprocated along the horizontal transfer rails 320. Thus, the horizontal transfer blocks 330 may reciprocate the laser irradiation module 200 in the horizontal direction.

As the horizontal transfer means 340, a means for reciprocating the horizontal transfer blocks 330 may be used. For example, the horizontal transfer means 340 may include a horizontal ball screw 341 and a horizontal servo motor 344. The horizontal ball screw 341 may include a horizontal screw shaft 342 and a horizontal nut 343. The horizontal ball screw 341 may be coupled to the horizontal transfer blocks 330 to move the horizontal transfer blocks 330. More specifically, the horizontal screw shaft 342 may be installed on the horizontal transfer support plate 310 in a direction parallel to the horizontal transfer rails 320. In addition, the horizontal screw shaft 342 is inserted into the horizontal nut 343, and the horizontal nut may be coupled to the horizontal transfer blocks 330, Further, the horizontal servo motor 344 may be coupled to the horizontal screw shaft 342 to rotate the horizontal screw shaft 342. As the horizontal screw shaft 342 is rotated, the horizontal nut 343 may be moved forwards and rearwards in the axial direction of the horizontal screw shaft 342, and may move the horizontal transfer block 330 forwards and rearwards. The horizontal transfer means 340 may reciprocate the horizontal transfer block 330 in the horizontal direction.

The horizontal transfer support column 350 may be formed in the shape of a box or a column extended in a vertical direction. The horizontal transfer support column 350 may be formed to have a hollow interior. The horizontal transfer support column 350 may be placed behind the horizontal transfer support plate 310, and may be coupled with the horizontal transfer support plate 310 to support the horizontal transfer support plate 310.

The vertical transfer module 400 may include a vertical ball screw 410, a vertical securing block 420, and a vertical rotation means 430. The vertical transfer module 400 is coupled to the horizontal transfer module 300 and may move the horizontal transfer module 300 in a vertical direction. More specifically, the vertical transfer module 400 may be coupled to the horizontal transfer support plate 310 to move the horizontal transfer support plate 310 upwards and downwards.

The vertical ball screw 410 may include a vertical screw shaft 411 and a vertical nut 412. The vertical ball screw 410 may be formed into the shape of a conventional ball screw. The vertical ball screw 410 may be placed behind the horizontal transfer module 300 to be extended in a vertical direction. The vertical ball screw 410 may be coupled to the horizontal transfer support column 350.

The vertical screw shaft 411 may be formed to be extended in a vertical direction. The vertical screw shaft 411 may be rotatably coupled to the horizontal transfer support column 350.

The vertical nut 412 may be upwardly and downwardly movably coupled to the vertical screw shaft 411. As the vertical screw shaft 411 is rotated, the vertical nut 412 may be moved upwards and downwards along the vertical screw shaft 411. The vertical nut 412 may be directly coupled to the horizontal transfer support plate 310.

The vertical securing block 420 may be formed in the shape of a block such as a column. The vertical securing block 420 may be coupled to the vertical nut 412. Further, the vertical securing block 420 may be coupled to a rear surface of the horizontal transfer support plate 310. Alternatively, the vertical securing block 420 may be integrally formed with the vertical nut 412. The vertical securing block 420 may be moved upwards and downwards, while supporting the horizontal transfer support plate 310. Accordingly, the vertical securing block 420 may move the horizontal transfer support plate 310 upwards and downwards.

A rotary knob may be used as the vertical rotation means 430. Further, a drive motor or a servo motor may be used as the vertical rotation means 430. The vertical rotation means 430 may be coupled to the vertical balls crew 410 to rotate the vertical ball screw 410. More specifically, the vertical rotation means 430 may be coupled to the vertical screw shaft 411 to rotate the vertical screw shaft 411.

In order to help those skilled in the art to understand, the embodiments disclosed herein are the most preferred embodiments selected from the various implementable embodiments, and are set forth in the present specification. In addition, the technical spirit of the present disclosure is not necessarily restricted or limited only by these embodiments, and various changes, additions, and modification are possible without departing from the technical spirit of the present disclosure, and implementations of other equivalent embodiments are possible.

1. A semiconductor chip laser bonding device, comprising:
a laser irradiation module having laser oscillating regions from which a laser beam is oscillated, the laser oscillating regions being extended in a first direction and spaced apar from each other in a second direction, and laser non-oscillating regions from which no laser beam is oscillated, each laser non-oscillating region being arranged between the laser oscillating regions; and
a horizontal transfer module configured to move the laser irradiation module in the second direction,
wherein when the laser irradiation module irradiates the laser beam onto an upper surface of a bonding substrate on which a semiconductor chip is mounted, the horizontal transfer module reciprocates the laser irradiation module in the second direction.

2. The semiconductor chip laser bonding device of claim 1, further comprising a bonding chamber, the bonding chamber comprising:
a chamber housing formed in the shape of box, configured to accommodate the bonding substrate therein, and having a laser passing opening formed in an upper plate and corresponding to the bonding substrate;
a substrate support supporting the bonding substrate inside the chamber housing; and
a laser transmitting plate coupled to the laser passing opening hole.

3. The semiconductor chip laser bonding device of claim 2, wherein the chamber housing further comprising:
a substrate entrance formed at one side wall and allowing the bonding substrate to enter the chamber housing, and a substrate exit formed on the other side wall and allowing the bonding substrate to be discharged to the outside; and
a gas inlet through which a gas flows into the chamber housing, and a gas outlet through which a gas is discharged to the outside.

4. The semiconductor chip laser bonding device of claim 1,
wherein the laser irradiation module is formed by arranging VCSEL devices in a lattice form on a lower surface of a device array plate,
wherein the VCSEL device has a device region on which laser emitting units, from which the laser beam is oscillated, are mounted, and a terminal region on which terminals supplying power to the laser emitting units are mounted,
wherein the device region forms the laser oscillating region and the terminal region forms the laser non-oscillation region.

5. The semiconductor chip laser bonding device of claim 4, wherein the laser oscillating region is formed to have a width greater than a width of the laser non-oscillating region, and the horizontal transfer module reciprocates the laser irradiation module a distance greater than a width of the laser non-oscillating region.

6. The semiconductor chip laser bonding device of claim 1, wherein the horizontal transfer module comprising:
a horizontal transfer support plate placed behind the laser irradiation module;
two horizontal transfer rails secured to a front surface of the horizontal transfer support plate while being extended in a horizontal direction and spaced apart from each other in a vertical direction;
a horizontal transfer block coupled to horizontal transfer rails and the laser irradiation module;
a horizontal transfer means configured to reciprocate the horizontal transfer block; and
a horizontal transfer support column placed behind the horizontal transfer support plate and coupled with the horizontal transfer support plate.

7. The semiconductor chip laser bonding device of claim 6, wherein the horizontal transfer means comprises a horizontal ball screw coupled to the horizontal transfer block to move the horizontal transfer block, and a horizontal servo motor coupled to the horizontal ball screw.

8. The semiconductor chip laser bonding device of claim 6, further comprising a vertical transfer module coupled to the horizontal transfer module to move the horizontal transfer module upwards and downwards.
